(19) United States
(12) Patent Application Publication
(10) Pub. No.: US 2023/0323105 A1
(43) Pub. Date: Oct. 12, 2023

(54) THERMOSETTING RESIN COMPOSITION, CURED MATERIAL THEREOF AND PREPREG, LAMINATE PROVIDED WITH CURED MATERIAL OR CURED MATERIAL OF PREPREG, METAL CLAD LAMINATE, AND PRINTED CIRCUIT BOARD

(71) Applicant: LG CHEM, LTD., Seoul (KR)

(72) Inventor: Shinji Shiraki, Tokyo (JP)

(21) Appl. No.: 18/019,732

(22) PCT Filed: Dec. 27, 2021
(86) PCT No.: PCT/KR2021/019927

§ 371 Date: Feb. 3, 2023

(30) Foreign Application Priority Data
Apr. 9, 2021 (JP) 2021-066425

(51) Int. Cl. C08J 5/24; C08L 53/02; C08K 7/16; C08G 81/02; H05K 1/03

(52) U.S. Cl. CPC C08L 53/02; C08G 81/025; C08J 5/24; C08K 7/16; H05K 1/036; C08J 2327/18; C08K 2201/005

(57) ABSTRACT

Provided is a thermosetting resin composition capable of forming a resin layer having sufficiently low relative dielectric constant and dissipation factor, and high flexibility and toughness in a relatively short period of time, a cured material thereof, a prepreg, a laminate, a metal clad laminate, and a printed circuit board. This is accomplished by a thermosetting resin composition including a (A) polymerizable polyphenylene ether compound of General Formula (1), an (B) elastomer, and a (C) tetrafluoroethylene-based polymer particle, wherein a content of (C) is from 1 parts by mass to 30 parts by mass, with respect to 100 parts by mass of the composition.

The present application is a National Phase entry pursuant to 35 U.S.C. § 371 of International Application No. PCT/KR2021/019927 filed on Dec. 27, 2021, and claims priority to and the benefit of Japanese Patent Application No. 2021-066425, filed with the Japanese Patent Office on Apr. 9, 2021, the entire contents of which are incorporated herein by reference.

### FIELD

The present disclosure relates to a thermosetting resin composition, a cured material thereof and a prepreg using the same, a laminate provided with a cured material or a cured material of the prepreg, a metal clad laminate, and a printed circuit board.

### BACKGROUND

In the recent field of information and communication, communication traffic is increasing due to an explosive supply of smart phones, and electronic devices relating to communication are required to process large amounts of data at a high speed. In addition, the number of channels increases by an increase in the number of wireless devices resulting from diversification of information or an increase in the amount of information handled, and accordingly, radio waves used for wireless information and communication increases to a high frequency. Therefore, communication devices used for information and communication are also required to respond to a high frequency. Thus, reducing transmission loss while delivering information during communication becomes important.

Transmission loss caused by thermal conversion of transmitted radio waves in wireless communication can be represented by the following Equation 1.

$$α = \text{K} \times \text{f} \times \sqrt{ε \text{r}} \times \text{tan} δ \qquad \text{[Equation 1]}$$

α: transmission loss of dielectric substance
K: proportional constant
f: frequency
εr: relative dielectric constant
tanδ: dissipation factor

In Equation 1, the amount of transmission loss is expressed as a product of a square root of a relative dielectric constant and a dissipation factor, and therefore, an antenna material exhibiting low dielectric properties is required to achieve communication with small loss. In particular, since a transmission signal in a high-frequency region has a property of being more readily converted to heat, a material exhibiting lower dielectric properties is required.

Thermosetting epoxy resins, polyimides that are a reaction product of aromatic tetracarboxylic anhydride and aromatic diamine, or the like, which are widely used as a substrate material in the art, include many polar groups for forming a network structure, and accomplishing low dielectric properties in such materials is considered to be very difficult.

Meanwhile, a resin material exhibiting low dielectric properties may include resin materials such as a fluorine resin represented by PTFE (polytetrafluoroethylene), a polyolefin-based thermoplastic resin such as polyethylene or polypropylene, or a liquid crystal polymer, and a copper laminate reinforced with a glass cloth or the like as necessary for dimensional stability or mechanical strength is used as an antenna or circuit material. These materials have favorable dielectric properties, but have major problems in moldability or heat resistance, and adhesiveness with a metal layer.

Recently, a resin layer formed by coating a resin composition including a resin powder formed with a resin material having, as main components, polyimide and a fluorine resin having an adhesive functional group such as a carbonyl -containing group, and a liquid medium on a substrate or metal clad surface, and drying and curing the result has been proposed (Patent Documents 1 and 2). Although the resin layer described in Patent Documents 1 and 2 has somewhat low relative dielectric constant and dissipation factor, further improvements in the transmission properties are particularly required in a printed circuit board used for high-speed transmission of a high-frequency signal after 5G, and materials having lower relative dielectric constant and dissipation factor have been required.

Meanwhile, a design technique achieving both electrical properties and heat resistance by modifying polyphenylene ether (hereinafter, described as PPE) through thermosetting has received attention. However, a cured film of PPE alone has a problem in flexibility, which leads to a problem of readily producing cracks after thermosetting. For this reason, a substrate design forming a network polymer employing a thermosetting resin represented by an epoxy resin as a common structure has been made, however, reducing a relative dielectric constant below a certain level becomes difficult in this case.

In addition, due to its excellent electrical properties (low dielectric constant and low dissipation factor), a styrene-based elastomer is a compound expected to be effective in increasing a transmission speed or reducing transmission loss. In order for a printed circuit board to have high performance and multilayer, attempts to use a laminate of a prepreg using this styrene-based elastomer as an insulation layer in a printed circuit board have been made (Patent Documents 3 to 5). However, a styrene-based elastomer generally has poor compatibility with resins, and has a drawback in that the styrene-based elastomer itself is peeled off and fell off when treated with a chemical liquid.

As a material of a printed circuit board, various resin compositions having these materials combined have been proposed. Patent Document 6 proposes a resin composition including a styrene-based elastomer, a styrene-based oligomer, a maleimide compound, a cyanate ester compound and polyphenylene ether. Patent Document 7 proposes a resin composition containing polyphenylene ether, an epoxy resin, a cyanate ester compound, an oligomer of styrene and/or substituted styrene, and an inorganic filler, however, none of these achieve high transmission properties. In addition, Patent Document 8 proposes a resin composition containing a thermosetting resin having a terminal styrene group and having a polyphenylene ether skeleton, a hydrogen added styrene-based thermoplastic elastomer and a polytetrafluoroethylene filler, and containing the polytetrafluoroethylene filler in greater than or equal to 40% by mass and less than or equal to 80% by mass, however, a cured film thereof is weak and has low physical strength required as a film such as flexibility and toughness, and accordingly, an application to a printed circuit board has been insufficient.

### Patent Documents

(Patent Document 1) International Publication No. 2016/017801
(Patent Document 2) Publication of Japanese Patent Application Laid-Open No. 2019-104843
(Patent Document 3) Publication of Japanese Patent No. 6167621
(Patent Document 4) Publication of Japanese Patent No. 6136348
(Patent Document 5) Publication of Japanese Patent Application Laid-Open No. 2011-001411
(Patent Document 6) International Publication No. 2019/230943
(Patent Document 7) Publication of Japanese Patent Application Laid-Open No. 2014-240474
(Patent Document 8) Publication of Japanese Patent Application Laid-Open No. 2016-89137

### SUMMARY

In the prior art, resin materials used in a printed circuit board for use in an electrical and electronic devices for a high-frequency signal or high-speed transmission of a higher level have not been obtained.

The present disclosure has been made in view of the above, and is directed to providing a thermosetting resin composition capable of forming a resin layer having sufficiently low relative dielectric constant and dissipation factor, high flexibility and toughness in a relatively short period of time, a cured material thereof, a prepreg provided with a layer formed with the thermosetting resin composition, a laminate provided with the cured material or a cured material of the prepreg, a metal clad laminate, and a printed circuit board.

As a result of close studies on the above problems, the inventors of the present disclosure have reached the present disclosure. In other words, one embodiment of the present disclosure provides a thermosetting resin composition including a (A) polymerizable polyphenylene ether compound of the following General Formula (1), an (B) elastomer, and a (C) tetrafluoroethylene-based polymer particle,

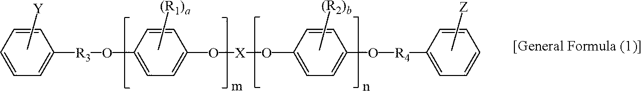

(in General Formula (1),
R₁ and R₂ each independently represent an alkyl group having 1 to 6 carbon atoms, an aryl group or halogen,
a and b each independently represent an integer of 0 to 4,
R₃ and R₄ each independently represent a single bond or an alkylene group having 1 to 6 carbon atoms,
X represents an arylene group,
Y and Z represent a polymerizable functional group, and
m and n each independently represent an integer of 1 to 100)
wherein a content of the (C) tetrafluoroethylene-based polymer particle is from 1 parts by mass to 30 parts by mass, with respect to 100 parts by mass of a solid content of the thermosetting resin composition.

In the (A) polymerizable polyphenylene ether compound used in the thermosetting resin composition of the present disclosure, X of General Formula (1) is preferably any one of the following General Formulae (2) to (4):

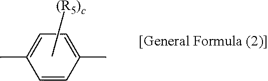

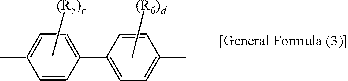

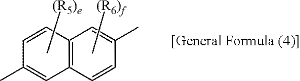

in General Formulae (2) to (4),
R₅ and R₆ each independently represent an alkyl group having 1 to 6 carbon atoms, an aryl group or halogen,
c and d each independently represent an integer of 0 to 4, and
e and f each independently represent an integer of 0 to 3.

In the (A) polymerizable polyphenylene ether compound used in the thermosetting resin composition of the present disclosure, the polymerizable functional groups Y and Z of General Formula (1) are preferably each independently selected from the group consisting of an alkenyl group, an acryloyl group and a methacryloyl group.

The (B) elastomer used in the thermosetting resin composition of the present disclosure is preferably a styrene-based elastomer.

The styrene-based elastomer used in the thermosetting resin composition of the present disclosure is preferably selected from the group consisting of a styrene-butadiene-styrene block copolymer, a styrene-isoprene-styrene block copolymer, a styrene-hydrogen added butadiene-styrene block copolymer, a styrene-hydrogen added isoprene-styrene block copolymer and a styrene-hydrogen added (isoprene/butadiene)-styrene block copolymer.

A content of the (B) elastomer used in the thermosetting resin composition of the present disclosure is preferably from 5 parts by mass to 40 parts by mass, with respect to 100 parts by mass of a solid content of the thermosetting resin composition.

The (C) tetrafluoroethylene-based polymer particle used in the thermosetting resin composition of the present disclosure is preferably represented by the following General Formula (5):

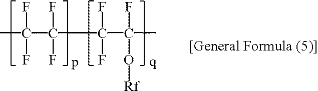

in General Formula (5),
Rf represents a fluoroalkyl group having 1 to 5 carbon atoms, and
p and q each independently represent an integer of 1 to 100000.

The (C) tetrafluoroethylene-based polymer particle used in the thermosetting resin composition of the present disclosure preferably has an average particle diameter in a range of 3 nm to 10 µm .

The thermosetting resin composition of the present disclosure preferably further includes a (D) fluorine-based surfactant.

The present disclosure also relates to a cured material of the thermosetting resin composition of the present disclosure.

The present disclosure also relates to a prepreg provided with a layer formed with the thermosetting resin composition of the present disclosure on a base material.

The present disclosure also relates to a laminate provided with the cured material of the present disclosure or a cured material of the prepreg of the present disclosure.

The present disclosure also relates to a metal clad laminate provided with a metal clad on one surface or both surfaces of the laminate of the present disclosure.

The present disclosure also relates to a printed circuit board having an insulation layer and a conductor layer on a surface of the insulation layer, wherein the insulation layer is provided with a layer formed with the thermosetting resin composition of the present disclosure.

According to a thermosetting resin composition of the present disclosure, a cured material thereof is capable of having sufficiently low relative dielectric constant and dissipation factor, and high flexibility and toughness.

According to the cured material of the present disclosure, or a cured material of a prepreg formed with the thermosetting resin composition, a laminate or a metal clad laminate having sufficiently low relative dielectric constant and dissipation factor, and high flexibility and toughness can be provided.

According to the thermosetting resin composition of the present disclosure, a printed circuit board having sufficiently low relative dielectric constant and dissipation factor and having high flexibility and toughness, and capable of withstanding heat and chemical treatments in a processing process can be provided.

### DETAILED DESCRIPTION

### Thermosetting Resin Composition

Hereinafter, a thermosetting resin composition of the present disclosure will be described in detail first. The thermosetting resin composition of the present disclosure includes a (A) polymerizable polyphenylene ether compound of the following General Formula (1), an (B) elastomer and a (C) tetrafluoroethylene-based polymer particle, wherein a content of the (C) tetrafluoroethylene-based polymer particle is from 1 parts by mass to 30 parts by mass, with respect to 100 parts by mass of a solid content of the thermosetting resin composition:

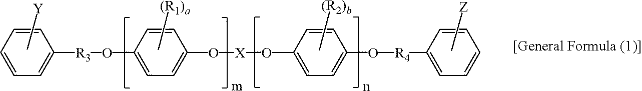

in General Formula (1),
R₁ and R₂ each independently represent an alkyl group having 1 to 6 carbon atoms, an aryl group or halogen,
a and b each independently represent an integer of 0 to 4,
R₃ and R₄ each independently represent a single bond or an alkylene group having 1 to 6 carbon atoms,
X represents an arylene group,
Y and Z represent a polymerizable functional group, and
m and n each independently represent an integer of 1 to 100.

### [(A) Polymerizable Polyphenylene Ether Compound]

R₁ and R₂ of General Formula (1) each independently represent an alkyl group having 1 to 6 carbon atoms, an aryl group or halogen, and are preferably an alkyl group having 1 to 6 carbon atoms. The alkyl group having 1 to 6 carbon atoms is preferably selected from the group consisting of a methyl group, an ethyl group, a propyl group, an isopropyl group, a butyl group, a t-butyl group, a pentyl group and a hexyl group, is preferably a methyl group or an ethyl group, and is more preferably a methyl group. The alkyl group having 1 to 6 carbon atoms may be substituted with an alkoxy group having 1 to 6 carbon atoms, an aryl group or halogen, and is not substituted preferably. The alkoxy group having 1 to 6 carbon atoms is preferably selected from the group consisting of a methoxy group, an ethoxy group, a propoxy group, a butoxy group, a pentyloxy group and a hexyloxy group. The aryl group is preferably selected from the group consisting of a phenyl group, a methylphenyl group, a chlorophenyl group, a fluorophenyl group, a methoxyphenyl group, a nitrophenyl group, a cyanophenyl group, a naphthyl group, a biphenyl group, an anthryl group, a phenanthryl group and a pyrenyl group.
a and b of General Formula (1) each independently represent an integer of 0 to 4, are preferably each independently an integer of 0 to 3, are more preferably each independently an integer of 1 to 2, and are most preferably 2.
R₃ and R₄ of General Formula (1) each independently represent a single bond or an alkylene group having 1 to 6 carbon atoms, are preferably selected from the group consisting of a methylene group, an ethylene group, a propylene group, a butylene group, a pentylene group and a hexylene group, are more preferably selected from the group consisting of a methylene group and an ethylene group, and are most preferably a methylene group. The alkylene group having 1 to 6 carbon atoms may be substituted with an alkoxy group having 1 to 6 carbon atoms, an aryl group or halogen, and is not substituted preferably.

X of General Formula (1) represents an arylene group, and is preferably selected from the group consisting of a phenylene group, a methylphenylene group, a chlorophenylene group, a fluorophenylene group, a methoxyphenylene group, a nitrophenylene group, a cyanophenylene group, a naphthylene group, a biphenylene group, an anthrylene group, a phenanthrene group and a pyrenylene group, and is more preferably selected from the group consisting of a phenylene group, a methylphenylene group, a naphthylene group and a biphenylene group. The arylene group may be substituted with an alkyl group having 1 to 6 carbon atoms, an alkoxy group having 1 to 6 carbon atoms, an aryl group or halogen, and is substituted with an alkyl group having 1 to 6 carbon atoms preferably.

In one embodiment, X of General Formula (1) is preferably any one of the following General Formulae (2) to (4), and more preferably General Formula (3). By using the polymerizable polyphenylene ether compound in which X is any one of General Formulae (2) to (4), the thermosetting resin composition of the present disclosure may bring favorable relative dielectric constant and dissipation factor.

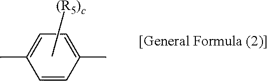

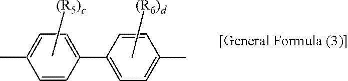

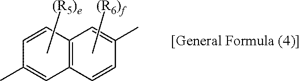

In General Formulae (2) to (4),
R₅ and R₆ each independently represent an alkyl group having 1 to 6 carbon atoms, an aryl group or halogen,
c and d each independently represent an integer of 0 to 4, and
e and f each independently represent an integer of 0 to 3.
R₅ and R₆ of General Formulae (2) to (4) each independently represent an alkyl group having 1 to 6 carbon atoms, an aryl group or halogen, and are preferably an alkyl group having 1 to 6 carbon atoms. The alkyl group having 1 to 6 carbon atoms is preferably selected from the group consisting of a methyl group, an ethyl group, a propyl group, an isopropyl group, a butyl group, a t-butyl group, a pentyl group and a hexyl group, is preferably a methyl group or an ethyl group, and is more preferably a methyl group. The alkyl group having 1 to 6 carbon atoms may be substituted with an alkoxy group having 1 to 6 carbon atoms, an aryl group or halogen, and is not substituted preferably. The alkoxy group having 1 to 6 carbon atoms is preferably selected from the group consisting of a methoxy group, an ethoxy group, a propoxy group, a butoxy group, a pentyloxy group and a hexyloxy group. The aryl group is preferably selected from the group consisting of a phenyl group, a methylphenyl group, a chlorophenyl group, a fluorophenyl group, a methoxyphenyl group, a nitrophenyl group, a cyanophenyl group, a naphthyl group, a biphenyl group, an anthryl group, a phenanthryl group and a pyrenyl group.
c and d of General Formulae (2) and (3) each independently represent an integer of 0 to 4, are preferably each independently an integer of 1 to 3, and are more preferably 3.

In one embodiment, Y and Z of General Formula (1) represent a polymerizable functional group, and are preferably each independently selected from the group consisting of an alkenyl group, an acryloyl group and a methacryloyl group, and are more preferably an alkenyl group. The alkenyl group is preferably selected from the group consisting of a vinyl group, a propenyl group, a butenyl group, a pentenyl group, a hexenyl group, a heptanyl group, an octenyl group, a decenyl group, a dodecenyl group, an octadecenyl group, a cyclobutenyl group, a cyclopentenyl group and a cyclohexenyl group, and is more preferably a vinyl group. Y and Z of General Formula (1) may be each independently selected from the group consisting of an alkenyl group, an acryloyl group and a methacryloyl group, a favorable cured film of the thermosetting resin composition is obtained.

m and n of General Formula (1) each independently represent an integer of 1 to 100, are preferably an integer of 1 to 10, and are more preferably an integer of 1 to 5. By m and n each independently representing an integer of 1 to 100, a favorable cured film of the thermosetting resin composition is obtained.

In one embodiment, a number average molecular weight of the (A) polymerizable polyphenylene ether compound is preferably in a range of 300 to 4000, and more preferably in a range of 500 to 3000. A favorable cured film of the thermosetting resin composition is obtained when the number average molecular weight is in a range of 300 to 4000. The measurement of the molecular weight is not particularly limited, however, for example, gel permeation chromatography is used, and the number average molecular weight of the (A) polymerizable polyphenylene ether compound may also be calculated from a calibration curve of a polystyrene standard.

In one embodiment, a content of the (A) polymerizable polyphenylene ether compound is preferably from 30 parts by mass to 94 parts by mass, more preferably from 40 parts by mass to 85 parts by mass, and most preferably from 50 parts by mass to 80 parts by mass, with respect to 100 parts by mass of a solid content of the thermosetting resin composition. By including the (A) polymerizable polyphenylene ether compound in the above-mentioned range, favorable relative dielectric constant and dissipation factor are obtained, and a favorable cured film of the thermosetting resin composition is obtained.

### [(B) Elastomer]

The (B) elastomer is preferably an elastomer compatible with the (A) polymerizable polyphenylene ether compound, and preferably selected from the group consisting of acrylic rubber, silicone rubber, ethylene-propylene rubber, polybutadiene, a cyclic olefin copolymer and a styrene-based elastomer.

In one embodiment, the (B) elastomer is preferably a styrene-based elastomer. By using a styrene-based elastomer, favorable relative dielectric constant and dissipation factor are obtained, and a favorable film of a cured material of the thermosetting resin composition is obtained.

In one embodiment, the styrene-based elastomer is preferably selected from the group consisting of a styrene-butadiene-styrene block copolymer, a styrene-isoprene-styrene block copolymer, a styrene-ethylene-styrene block copolymer, a styrene-propylene-styrene block copolymer, a styrene-ethylene/propylene-styrene block copolymer, a styrene-ethylene/butylene-styrene block copolymer, a styrene-hydrogen added butadiene-styrene block copolymer, a styrene-hydrogen added isoprene-styrene block copolymer and a styrene-hydrogen added (isoprene/butadiene)-styrene block copolymer, and more preferably a styrene-hydrogen added butadiene-styrene block copolymer.

In one embodiment, a content of the (B) elastomer is preferably from 5 parts by mass to 40 parts by mass, more preferably from 10 parts by mass to 40 parts by mass, and most preferably from 15 parts by mass to 40 parts by mass, with respect to 100 parts by mass of a solid content of the thermosetting resin composition. By including the (B) elastomer in the above-mentioned range, favorable relative dielectric constant and dissipation factor are obtained, and a favorable cured film of the thermosetting resin composition is obtained.

### [(C) Tetrafluoroethylene-Based Polymer Particle]

The tetrafluoroethylene-based polymer is preferably selected from the group consisting of a tetrafluoroethylene homopolymer, a copolymer (ETFE) of tetrafluoroethylene and ethylene, a copolymer of tetrafluoroethylene and propylene, a copolymer (PFA) of tetrafluoroethylene and perfluoro(alkyl vinyl ether) (PAVE), a copolymer (FEP) of tetrafluoroethylene and hexafluoropropylene (HFP), a copolymer of tetrafluoroethylene and fluoroalkyl ethylene (FAE), a copolymer of tetrafluoroethylene and fluoroalkyl fluoroethylene, and a copolymer of tetrafluoroethylene and chlorotrifluoroethylene (CTFE).

In one embodiment, the tetrafluoroethylene-based polymer preferably includes a repeating unit of the following General Formula (5) or (6).

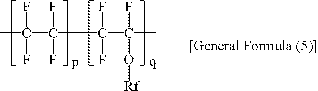

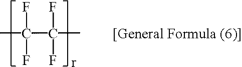

In General Formulae (5) and (6),
Rf represents a fluoroalkyl group having 1 to 5 carbon atoms, and
p, q and r each independently represent an integer of 1 to 100000.

In one embodiment, the tetrafluoroethylene-based polymer preferably includes the repeating unit of General Formula (5). By using the tetrafluoroethylene-based polymer particle of General Formula (5), a thermosetting resin in which particles are more favorably dispersed may be obtained.

The fluoroalkyl group having 1 to 5 carbon atoms is preferably selected from the group consisting of a trifluoromethyl group, a difluoromethyl group, a perfluoroethyl group, a 2,2,2-trifluoroethyl group, a 1,1,2,2-tetrafluoroethyl group, a perfluoropropyl group, a 2,2,3,3,3-pentafluoropropyl group, a perfluorobutyl group, a 1,1,2,2,3,3,4,4-octafluorobutyl group, a perfluoropentyl group and a 2,2,3,3,4,4,5,5,5-nonafluoropentyl group, more preferably a trifluoromethyl group, a difluoromethyl group, a perfluoroethyl group or a perfluoropropyl group, and most preferably a perfluoropropyl group.

In one embodiment, the (C) tetrafluoroethylene-based polymer particle is preferably in a powder form, and is mixed in the thermosetting resin composition in a state of being dispersed into any solvent or water. In the thermosetting resin composition, the (C) tetrafluoroethylene-based polymer particle is present in a state of being dispersed into a matrix of the (A) polymerizable polyphenylene ether compound and the (B) elastomer.

In one embodiment, an average particle diameter of the (C) tetrafluoroethylene-based polymer particle is preferably in a range of 3 nm to 10 µm, more preferably in a range of 10 nm to 5 µm, and most preferably in a range of 20 nm to 3 µm. The measurement of the average particle diameter of the (C) tetrafluoroethylene-based polymer particle is not particularly limited, however, for example, volume particle size distribution is measured using a laser diffraction type particle size distribution measurement device, and a central particle diameter (D50) in the volume particle size distribution may be employed as the average particle diameter.

A content of the (C) tetrafluoroethylene-based polymer particle is from 1 parts by mass to 30 parts by mass, preferably from 2 parts by mass to 20 parts by mass, and more preferably from 3 parts by mass to 15 parts by mass, with respect to 100 parts by mass of a solid content of the thermosetting resin composition. When the content of the (C) tetrafluoroethylene-based polymer particle is less than 1 parts by mass, favorable relative dielectric constant and dissipation factor are not obtained, and when the content is greater than 30 parts by mass, a cured film of the thermosetting resin composition having favorable flexibility and toughness is not obtained.

### (D) Fluorine-Based Surfactant

The thermosetting resin composition of the present disclosure preferably further includes a (D) fluorine-based surfactant. By including the (D) fluorine-based surfactant, the (C) tetrafluoroethylene-based polymer particle may be stably dispersed into the thermosetting resin composition. Although a type of the (D) fluorine-based surfactant is not particularly limited, a nonionic surfactant containing a fluorine atom is preferred. According to one embodiment of the present disclosure, Megaface F-444, Megaface F-445, Megaface F-470, Megaface F-477 and Megaface MCF-350SF manufactured by DIC Corporation, Ftergent 710FL, Ftergent 710FM, Ftergent 710FS, Ftergent 730LM, Ftergent 610FM, Ftergent 683, Ftergent 601AD, Ftergent 601ADH2, Ftergent 602A, Ftergent 650AC and Ftergent 681 manufactured by NEOS Company Limited., FD-420 manufactured by Kyoeisha Chemical Co., Ltd., and the like may be used as a commercial product of the fluorine-based surfactant.

In one embodiment, a content of the (D) fluorine-based surfactant is, when converted based on a solid content of the fluorine-based surfactant, from 0.01 parts by mass to 100 parts by mass, preferably from 0.1 parts by mass to 80 parts by mass, and more preferably from 1 parts by mass to 60 parts by mass, with respect to 100 parts by mass of the (C) tetrafluoroethylene-based polymer particle.

To the thermosetting resin composition, a solvent, a silane coupling agent, a crosslinking compound, a catalyst and the like may be added as long as they are in ranges not harming effects of the present disclosure.

As for the thermosetting resin composition of the present disclosure, the composition solution may be prepared by dissolving the corresponding composition in a solvent together with various additives mixed as necessary so that the solid content concentration becomes, for example, 3% by weight to 90% by weight.

The solvent used in preparing the composition solution is not particularly limited as long as it is mixed with the components of the thermosetting resin composition and has favorable solubility. Specific examples thereof may include the group consisting of ketones such as acetone, methyl ethyl ketone, methyl isobutyl ketone and cyclohexanone, aromatic hydrocarbons such as benzene, toluene and xylene, amides such as dimethylformamide and dimethylacetamide, aliphatic alcohols such as methyl cellosolve, ethyl cellosolve, methyl cellosolve acetate, ethyl cellosolve acetate and butyl cellosolve, ethers such as propylene glycol methyl ether acetate, propylene glycol ethyl ether acetate and propylene glycol propyl ether acetate, and esters such as methyl 2-hydroxypropionate, ethyl 2-hydroxypropionate, ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl oxyacetate, methyl 2-hydroxy-3-methylbutanoate, 3-methyl-3-methoxybutyl acetate, 3-methyl-3-methoxybutyl propionate, 3-methyl-3-methoxybutyl butanoate, ethyl acetate, butyl acetate, methyl pyruvate and ethyl pyruvate, and these may be used either alone or as a mixture of two or more types.

Among these solvents, a solvent having a low boiling point and low polarity is suitable for the composition of the present disclosure in order to reduce the influence of a residual solvent after drying and curing on dielectric properties. Toluene and xylene are particularly preferred.

### Cured Material

The present disclosure also relates to a cured material of the thermosetting resin composition of the present disclosure.

The cured material of the present disclosure may be obtained by polymerizing the polymerizable functional groups X and Y of the (A) polymerizable polyphenylene ether compound included in the thermosetting resin composition by heat. The curing may use a method of heating in a dryer or a furnace, or a method of heating on a hot plate when on a relatively small base material. The curing temperature is not particularly limited, but is approximately from 80° C. to 300° C. and preferably from 90° C. to 250° C. The curing time is not particularly limited as well, but is from 10 minutes to 180 minutes, and preferably from 20 minutes to 120 minutes when using a dryer or a furnace. In addition, the curing time is from 1 minute to 30 minutes, and preferably from 2 minutes to 15 minutes when using a hot plate.

In one embodiment, the cured material has a relative dielectric constant of 2.5 or less, preferably 2.3 or less, and more preferably 2.2 or less.

In one embodiment, the cured material has a dissipation factor of 0.005 or less, preferably 0.002 or less, and more preferably 0.001 or less.

### Prepreg

The present disclosure also relates to a prepreg provided with a layer formed with the thermosetting resin composition of the present disclosure. A prepreg means the thermosetting resin composition of the present disclosure being impregnated into or coated on a fiber base material in a semi-cured state.

In one embodiment, the fiber base material is not particularly limited, however, a glass fiber base material, a carbon fiber base material, a cellulose fiber base material, a synthetic fiber base material formed with a woven or non-woven fabric employing a polyamide-based resin fiber such as a polyamide resin fiber or an aromatic polyamide resin fiber, a polyester-based resin fiber such as a polyester resin fiber, an aromatic polyester resin fiber or a wholly aromatic polyester resin fiber, a polyimide resin fiber, a fluorine resin fiber and the like as a main component, a paper base material employing a kraft paper, a cotton linter paper, a blend paper of linter and kraft pulp, and the like may be used. Preferably, a glass fiber base material, a carbon fiber base material or a cellulose fiber base material is used. A glass fiber base material, a carbon fiber base material or a cellulose fiber base material is capable of enhancing strength of the prepreg, reducing an absorption rate, and also decreasing a thermal expansion coefficient.

In one embodiment, the prepreg may be prepared using, although not particularly limited thereto, methods well known in the art. For example, a method for preparing the prepreg may use an impregnation method, a coating method using various coaters, a spray spraying method or the like.

In one embodiment, a condition for preparing the prepreg is not particularly limited, however, using in a varnish state by adding a solvent to the thermosetting resin composition is preferred. The solvent for varnish is not particularly limited as long as it is mixable with the components of the thermosetting resin composition and has favorable solubility. Specific examples thereof may be selected from the group consisting of ketones such as acetone, methyl ethyl ketone, methyl isobutyl ketone and cyclohexanone, aromatic hydrocarbons such as benzene, toluene and xylene, amides such as dimethylformamide and dimethylacetamide, and aliphatic alcohols such as methyl cellosolve and butyl cellosolve.

In one embodiment, it is preferred that, when preparing the prepreg, a semi-cured state is obtained by volatizing 80% by weight or more of the solvent used. A drying condition for this is not particularly limited, and a method of heating in a dryer or a furnace, or, when on a relatively small base material, a method of heating on a hot plate may also be used. The temperature when drying is approximately from 80° C. to 300° C. and preferably from 90° C. to 250° C., and although the curing time is not particularly limited, the time is from 10 minutes to 180 minutes and preferably from 20 minutes to 120 minutes when using a dryer or a furnace. In addition, the curing time is from 1 minute to 30 minutes and preferably from 2 minutes to 15 minutes when using a hot plate.

In one embodiment, an amount of the thermosetting resin composition in the prepreg is preferably in a range of 20 parts by mass to 90 parts by mass and preferably 30 parts by mass to 80 parts by mass, with respect to a total amount of the prepreg.

### Laminate

The present disclosure also relates to a laminate provided with the cured material of the present disclosure, or a cured material of the prepreg of the present disclosure. In one embodiment, the laminate preferably includes the cured material of the present disclosure or a cured material of the prepreg, and a base material. For example, a laminate having a base material/the cured material or a cured material of the prepreg, a constitution of a base material/the cured material or a cured material of the prepreg/a base material, or a multilayer lamination structure of a constitution of additionally laminating a base material and the cured material or a cured material of the prepreg may be included.

The laminate is preferably obtained by coating the thermosetting resin composition of the present disclosure on a base material. As the coating method, a bar coating method, a roll coating method, an air knife method, a gravure method, a reverse roll method, a kiss roll method, a doctor blade method, a die coating method, a micro gravure coating method, a comma coating method, a slot die coating method, a lip coating method, a spray method, an immersion method, a brushing method, a solution casting method or the like may be used. In addition, coating using a spin coating method may also be used when on a relatively small base material. As for the drying condition, the temperature is not particularly limited as long as it is a temperature at which the thermosetting resin composition of the present disclosure is cured and the solvent sufficiently volatizes, and the temperature when drying is approximately from 80° C. to 300° C. and preferably from 90° C. to 250° C. The drying method is not particularly limited as well, and a method of heating in a dryer or a furnace, or, when on a relatively small base material, a method of heating on a hot plate may also be used. In addition, the time is from 10 minutes to 180 minutes and preferably from 20 minutes to 120 minutes when using a dryer or a furnace. In addition, the time is from 1 minute to 30 minutes and preferably from 2 minutes to 15 minutes when using a hot plate.

The base material is not particularly limited, and examples thereof may include organic-based film base materials such as a polyethylene film, a polypropylene film, a polycarbonate film, a polyethylene terephthalate film, an ethylene tetrafluoroethylene copolymer film, a release film having a release agent coated on a surface of these films, and a polyimide film, metal clads such as copper foil and aluminum foil, and plates such as a glass plate, a SUS plate and FRP.

In one embodiment, thicknesses of the cured material of the present disclosure or a cured material of the prepreg of the present disclosure and the base material in the laminate are each preferably from 0.1 µm to 500 µm.

### Metal Clad Laminate

The present disclosure also relates to a metal clad laminate provided with a metal clad on one surface or both surfaces of the laminate of the present disclosure. In one embodiment, obtaining a metal clad laminate having a metal clad integrated with a cured material of the prepreg by heating and pressurizing the metal clad together with the prepreg of the present disclosure is preferred.

The metal clad may be copper foil. The copper foil may be copper or a copper alloy, or may be selected from among rolled copper foil or electrolytic copper foil. In addition, the metal may be formed as a film on the prepreg of the present disclosure or on a release film, and as for the film-forming method, a metal thin film of copper or copper alloy may be formed using a gas deposition method such as a vacuum deposition method, an ion plating method, a sputtering method or a CVD method, or a wet method such as an electroplating method or an electroless plating method. In addition, in one embodiment, the metal clad has a thickness of preferably 0.5 µm to 70 µm and more preferably 2 µm to 35 µm.

In one embodiment, when processing the metal clad and the prepreg of the present disclosure, heating at 100° C. to 300° C., preferably at 200° C. or higher and more preferably at 220° C. or higher is preferred, and pressurizing at 2 kgf/cm² to 100 kgf/cm² and preferably at 35 kgf/cm² to 50 kgf/cm² is preferred. The time for heating and/or pressurizing is preferably from 0.05 hours to 5 hours.

### Printed Circuit Board

The present disclosure also relates to a printed circuit board having an insulation layer and a conductor layer on a surface of the insulation layer, wherein the insulation layer is provided with a layer formed with the thermosetting resin composition of the present disclosure. In one embodiment, the printed circuit board may be manufactured using a laminate or a metal clad laminate including the prepreg of the present disclosure.

In one embodiment, the printed circuit board may be manufactured using methods well known in the art, and for example, an etching-treated metal clad laminate is employed as an inner layer substrate, and by laminating the prepreg and/or the laminate of the present disclosure thereon, a laminate having a metal clad in an outer layer is obtained, and a laminate in which a base material and an insulation layer formed with a cured material of the thermosetting resin composition are formed between the inner layer circuit and the metal clad of the outer layer may be obtained. In addition, the printed circuit board may be obtained by electrically conducting the inner layer circuit and the outer layer circuit and installing an etching circuit in the metal clad of the outer layer circuit.

### EXAMPLES[EXAMPLE 1]

### Preparation of Thermosetting Resin Composition A1

6 g of polyphenylene ether A1 (OPE-2St 1200 manufactured by Mitsubishi Gas Chemical Company Inc., number average molecular weight 1200), 4 g of hydrogen added styrene-butadiene-styrene block copolymer B1 (SEPTON 8007L manufactured by Kuraray Inc.) and 15 g of toluene were introduced and mixed. Then, 1 g of polytetrafluoroethylene particle C1 (MICRODISPERS-200 manufactured by Polysciences Inc.) and 0.05 g of fluorine-based surfactant D1 (Ftergent 710FL manufactured by NEOS Company Limited., the amount converted based on a solid content of the fluorine-based surfactant) were introduced to this mixture solution, and the result was stirred and mixed to obtain thermosetting resin composition a1 as a polytetrafluoroethylene particle dispersion.

### Manufacture of Element for Measuring Relative Dielectric Constant and Dissipation Factor

A metal mask having an electrode pattern was installed on a glass substrate, and the result was introduced to a chamber of a 3-way sputter device EIS-230P manufactured by Elionix Inc. Inside the chamber was evacuated to 3×10⁻⁴ Pa or less, then argon gas (concentration: 99.9%) was introduced thereto at a flow rate of 1 sccm, and aluminum sputtering was conducted under a degree of vacuum of 3×10⁻³ Pa in the chamber to form a base electrode of an aluminum thin film having a film thickness of 100 nm. This was taken out of the chamber, the thermosetting resin composition a1 was coated on the substrate having a portion of a lower electrode covered with a Kapton tape by spin coating, and the Kapton tape was peeled off to expose the taken-out electrode. Subsequently, the result was dried for 1 minute on a hot plate set to 90° C., and then heated for 3 minutes on a hot plate set to 200° C. After that, as in the formation of the lower electrode, aluminum sputtering was conducted through a metal mask, and an upper electrode having a film thickness of 100 nm was formed so as to have an outlet on the opposite side to the lower electrode.

### Evaluation Test

For the coated film of the composition obtained above, an evaluation test was conducted using the following methods.
(1) Film thickness: The film thickness of the cured film was measured using a stylus-type profilometer (Dektak XT manufactured by Bruker).
(2) Cracking: For the surface of the cured film, the presence or absence of cracks was observed using an optical microscope. (O: no cracks, X: cracks occurred)
(3) Relative dielectric constant, dissipation factor: A four-terminal probe L2000 was attached to an LCR meter (IM3536 manufactured by Hioki E.E. Corporation), and at room temperature (25° C.), and dielectric constant and dissipation factor tanδ of the cured film sandwiched between the upper electrode and the lower electrode of the element manufactured above at a frequency of 1 MHz were measured, and a relative dielectric constant was calculated.
(4) Chemical resistance: The cured film was immersed in toluene for 24 hours at room temperature (25° C.), and changes in the appearance were observed. (O: no changes, X: dissolution or peeling occurred)
(5) Dispersibility: The thermosetting resin composition was left still for 10 days at room temperature (25° C.), and an occurrence of precipitation of the polytetrafluoroethylene particles on the third day and the tenth day was observed. (X: precipitation occurred on the third day, O: no precipitation on the third day, O: no precipitation on the tenth day)

Evaluation results of Example 1 are shown in [Table 1].

### Example 2

8 g of polyphenylene ether A1 (OPE-2St 1200 manufactured by Mitsubishi Gas Chemical Company Inc., number average molecular weight 1200), 2 g of hydrogen added styrene-butadiene-styrene block copolymer B1 (SEPTON 8007L manufactured by Kuraray Inc.) and 15 g of toluene were introduced and mixed. Then, 0.5 g of polytetrafluoroethylene particle C1 (MICRODISPERS-200 manufactured by Polysciences Inc.) and 0.025 g of fluorine-based surfactant D1 (Ftergent 710FL manufactured by NEOS Company Limited., the amount converted based on a solid content of the fluorine-based surfactant) were introduced to this mixture solution, and the result was stirred and mixed to obtain thermosetting resin composition a2 as a polytetrafluoroethylene particle dispersion. An element was manufactured in the same manner as in Example 1 except that a2 was used as the thermosetting resin composition, and the evaluation test was conducted. Evaluation results of Example 2 are also shown in [Table 1].

### Example 3

7 g of polyphenylene ether A1 (OPE-2St 1200 manufactured by Mitsubishi Gas Chemical Company Inc., number average molecular weight 1200), 3 g of hydrogen added styrene-butadiene-styrene block copolymer B1 (SEPTON 8007L manufactured by Kuraray Inc.) and 15 g of toluene were introduced and mixed. Then, 1 g of tetrafluoroethylene-based polymer particle C2 (tetrafluoroethylene/perfluoroalkyl vinyl ether copolymer, Fluon+EA-2000 PW10 manufactured by AGC Inc.) and 0.05 g of fluorine-based surfactant D2 (FD-420 manufactured by Kyoeisha Chemical Co., Ltd., the amount converted based on a solid content of the fluorine-based surfactant) were introduced to this mixture solution, and the result was stirred and mixed to obtain thermosetting resin composition a3 as a tetrafluoroethylene-based polymer particle dispersion. An element was manufactured in the same manner as in Example 1 except that a3 was used as the thermosetting resin composition, and the evaluation test was conducted. Evaluation results of Example 3 are also shown in [Table 1].

### Example 4

An element was manufactured in the same manner as in Example 3 except for using thermosetting resin composition a4 obtained as a tetrafluoroethylene-based polymer particle dispersion by stirring and mixing as in Example 3 without introducing the fluorine-based surfactant D2, and the evaluation test was conducted. Evaluation results of Example 4 are also shown in [Table 1].

### [Comparative Example 1]

Thermosetting resin composition a5 was obtained in the same manner as in Example 3 without mixing the tetrafluoroethylene-based polymer particle C2 and the fluorine-based surfactant D2. An element was manufactured in the same manner as in Example 3 except that a5 was used as the thermosetting resin composition, and the evaluation test was conducted. Evaluation results of Comparative Example 1 are also shown in [Table 1].

### [Comparative Example 2]

Thermosetting resin composition a6 was obtained as a tetrafluoroethylene-based polymer particle dispersion in the same manner as in Example 3, except that 0.05 g of tetrafluoroethylene-based polymer particle C2 (tetrafluoroethylene/perfluoroalkyl vinyl ether copolymer, Fluon+EA-2000 PW10 manufactured by AGC Inc.) and 0.0025 g of fluorine-based surfactant D2 (FD-420 manufactured by Kyoeisha Chemical Co., Ltd., the amount converted based on a solid content of the fluorine-based surfactant) were introduced, and stirred and mixed. An element was manufactured in the same manner as in Example 3 except that a6 was used as the thermosetting resin composition, and the evaluation test was conducted. Evaluation results of Comparative Example 2 are also shown in [Table 1].

### [Comparative Example 3]

Thermosetting resin composition a7 was obtained as a tetrafluoroethylene-based polymer particle dispersion in the same manner as in Example 3, except that 5 g of tetrafluoroethylene-based polymer particle C2 (tetrafluoroethylene/perfluoroalkyl vinyl ether copolymer, Fluon+EA-2000 PW10 manufactured by AGC Inc.) and 0.25 g of fluorine-based surfactant D2 (FD-420 manufactured by Kyoeisha Chemical Co., Ltd., the amount converted based on a solid content of the fluorine-based surfactant) were introduced, and stirred and mixed. An element was manufactured in the same manner as in Example 3 except that a7 was used as the thermosetting resin composition, and the evaluation test was conducted. Evaluation results of Comparative Example 3 are also shown in [Table 1].

### [Comparative Example 4]

Thermosetting resin composition a8 was obtained as a tetrafluoroethylene-based polymer particle dispersion in the same manner as in Example 3, except that 10 g of polyphenylene ether A1 (OPE-2St 1200 manufactured by Mitsubishi Gas Chemical Company Inc., a number average molecular weight 1200) and 15 g of toluene were introduced and mixed without using the hydrogen added styrene-butadiene-styrene block copolymer. Then, 1 g of tetrafluoroethylene-based polymer particle C2 (tetrafluoroethylene/perfluoroalkyl vinyl ether copolymer, Fluon+EA-2000 PW10 manufactured by AGC Inc.) and 0.05 g of fluorine-based surfactant D2 (FD-420 manufactured by Kyoeisha Chemical Co., Ltd., the amount converted based on a solid content of the fluorine-based surfactant) were introduced to this mixture solution, and the result was stirred and mixed to obtain thermosetting resin composition a8 as a tetrafluoroethylene-based polymer particle dispersion. An element was manufactured in the same manner as in Example 1 except that a8 was used as the thermosetting resin composition, and the evaluation test was conducted. Evaluation results of Comparative Example 4 are also shown in [Table 1].

An explanation on the descriptions in Table 1 is as follows.
A1: polyphenylene ether, OPE-2St 1200 manufactured by Mitsubishi Gas Chemical Company Inc., number average molecular weight 1200
B1: hydrogen added styrene-butadiene-styrene block copolymer particles, SEPTON 8007L manufactured by Kuraray Inc.
C1: polytetrafluoroethylene particles, MICRODISPERS-200 manufactured by Polysciences Inc., particle diameter 200 nm to 300 nm
   C2: tetrafluoroethylene/perfluoroalkyl vinyl ether copolymer, Fluon+EA-2000 PW10 manufactured by AGC Inc., particle diameter D50=3 µm
D1: fluorine-based surfactant, Ftergent 710FL manufactured by NEOS Company Limited.
   D2: fluorine-based surfactant, FD-420 manufactured by Kyoeisha Chemical Co., Ltd.

The numbers in ( ) represent the solid content of each component.

TABLE 1

| | Example 1 | Example 2 | Example 3 | Example 4 | Comp. Ex. 1 | Comp. Ex 2 | Comp. Ex. 3 | Comp. Ex. 4 |
|---|---|---|---|---|---|---|---|---|
| Thermosetting Resin Composition | a1 | a2 | a3 | a4 | a5 | a6 | a7 | a8 |
| (A) Polymerizable Polyphenylene Ether Compound | A1 (6) | A1 (8) | A1 (7) | A1 (7) | A1 (7) | A1 (7) | A1 (7) | A1 (10) |
| (B) Elastomer | B1 (4) | B1 (2) | B1 (3) | B1 (3) | B1 (3) | B1 (3) | B1 (3) | None |
| (C) Tetrafluoroeth ylene-based Polymer Particle | C1 (1) | C1 (0.5) | C2 (1) | C2 (1) | None | C2 (0.05) | C2 (5) | C2 (1) |
| (D) Fluorine-based Surfactant | D1 (0.05) | D1 (0.025) | D2 (0.05) | None | None | D2 (0.0025) | D2 (0.25) | D2 (0.05) |
| Thickness of Cured Film (µm) | 10 | 10 | 10 | 10 | 10 | 10 | 10 | 10 |
| Cracking | 0 | 0 | 0 | 0 | 0 | 0 | 0 | X |
| Relative Dielectric Constant (1 MHz) | 2.42 | 2.46 | 2.43 | 2.43 | 2.62 | 2.60 | 2.35 | Unable to Measure |
| Dissipation Factor (1 MHz) | 0.0019 | 0.0021 | 0.0018 | 0.0018 | 0.0029 | 0.0028 | Unable to Measure | Unable to Measure |
| Chemical Resistance | 0 | 0 | 0 | 0 | 0 | 0 | X | X |
| Dispersibility | ⓞ | ⓞ | ⓞ | 0 | - | ⓞ | X | ⓞ |

### Results

In Comparative Example 3 of [Table 1], the tetrafluoroethylene-based polymer particle C2 was not uniformly dispersed in the resin solution, and a reproducible dissipation factor value was not obtained due to the surface unevenness of the coated film. In addition, in Comparative Example 4, peeling caused by cracks occurred on the whole cured film surface, and a relative dielectric constant and a dissipation factor were not able to be measured.

In all of the Examples, the relative dielectric constant is 2.5 or less and the dissipation factor value is 0.002 or less, which are very small, allowing small transmission loss. In addition, cracking, chemical resistance and dispersibility are also favorable, and it is seen that a cured film having high heat resistance and durability is obtained. Meanwhile, when the components included in the composition of the present disclosure are not included or the content of each component is outside the range of the present disclosure, problems such as increases in the relative dielectric constant and the dissipation factor values (Comparative Examples 1 and 2), decreases in the chemical resistance and the dispersibility (Comparative Example 3) and an occurrence of cracks (Comparative Example 4) occur.

The laminate of the present disclosure has no restrictions other than those disclosed above, and may be used as a substrate of a printed circuit board and the like, and, with its superior relative dielectric constant and dissipation factor and flexibility and toughness of the cured film, is also suitable to be used in a printed circuit board requiring high frequency and high-speed transmission compared to those used in the art.

1. A thermosetting resin composition comprising:
a (A) polymerizable polyphenylene ether compound of the following General Formula (1);
an (B) elastomer; and
(C) tetrafluoroethylene-based polymer particles,
wherein a content of the (C) tetrafluoroethylene-based polymer particles is from 1 parts by mass to 30 parts by mass with respect to 100 parts by mass of a solid content of the thermosetting resin composition: 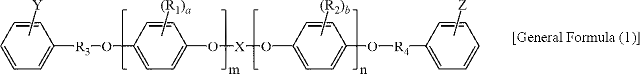
in General Formula (1),
R₁ and R₂ each independently represent an alkyl group having 1 to 6 carbon atoms, an aryl group or halogen,
a and b each independently represent an integer of 0 to 4,
R₃ and R₄ each independently represent a single bond or an alkylene group having 1 to 6 carbon atoms,
X represents an arylene group,
Y and Z represent a polymerizable functional group, and
m and n each independently represent an integer of 1 to 100.

2. The thermosetting resin composition of claim 1, wherein X of General Formula (1) is any one of the following General Formulae (2) to (4): 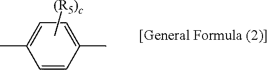 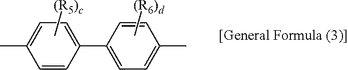 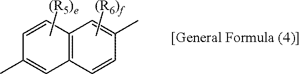
in General Formulae (2) to (4),
R₅ and R₆ each independently represent an alkyl group having 1 to 6 carbon atoms, an aryl group or halogen,
c and d each independently represent an integer of 0 to 4, and
e and f each independently represent an integer of 0 to 3.

3. The thermosetting resin composition of claim 1, wherein the polymerizable functional groups Y and Z of General Formula (1) are each independently selected from the group consisting of an alkenyl group, an acryloyl group and a methacryloyl group.

4. The thermosetting resin composition of claim 1, wherein the (B) elastomer is a styrene-based elastomer.

5. The thermosetting resin composition of claim 4, wherein the styrene-based elastomer is selected from the group consisting of a styrene-butadiene-styrene block copolymer, a styrene-isoprene-styrene block copolymer, a styrene-hydrogen added butadiene-styrene block copolymer, a styrene-hydrogen added isoprene-styrene block copolymer and a styrene-hydrogen added (isoprene/butadiene)-styrene block copolymer.

6. The thermosetting resin composition of claim 1, wherein a content of the (B) elastomer is from 5 parts by mass to 40 parts by mass, with respect to 100 parts by mass of a solid content of the thermosetting resin composition.

7. The thermosetting resin composition of claim 1, wherein the (C) tetrafluoroethylene-based polymer particle includes a repeating unit of the following General Formula (5): 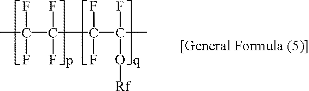
in General Formula (5),
Rf represents a fluoroalkyl group having 1 to 5 carbon atoms, and
p and q each independently represent an integer of 1 to 100000.

8. The thermosetting resin composition of claim 1, wherein the (C) tetrafluoroethylene-based polymer particles have an average particle diameter in a range of 3 nm to 10 µm.

9. The thermosetting resin composition of claim 1, further comprising a (D) fluorine-based surfactant.

10. A cured material of the thermosetting resin composition of claim 1.

11. A prepreg provided with a layer formed with the thermosetting resin composition of claim 1 on a base material.

12. A laminate provided with the cured material of claim 10.

13. A metal clad laminate provided with a metal clad on one surface or both surfaces of the laminate of claim 12.

14. A printed circuit board comprising:
an insulation layer; and
a conductor layer on a surface of the insulation layer,
wherein the insulation layer is provided with a layer formed with the thermosetting resin composition of claim 1.
